(19) United States
(12) Patent Application Publication
(10) Pub. No.: US 2026/0314084 A1
(43) Pub. Date: Oct. 8, 2026

(54) SOLAR PANEL INCLUDING RECYCLABLE PACKAGE ENCAPSULATING PHOTOVOLTAIC CELLS

(71) Applicant: CORNING INCORPORATED, CORNING, NY (US)

(72) Inventors: Albert Joseph Fahey, Corning, NY (US); Shandon Dee Hart, Elmira, NY (US); Stephen Kuenzli, Mansfield, PA (US); Alexandra Lai Ching Kao Andrews Mitchell, Ithaca, NY (US); Steven Akira Yamada, Painted Post, NY (US)

(21) Appl. No.: 19/481,626

(22) PCT Filed: May 15, 2024
(86) PCT No.: PCT/US2024/029357

§ 371 Date: Nov. 5, 2025

Related U.S. Application Data
(60) Provisional application No. 63/467,714, filed on May 19, 2023.

(51) Int. Cl. H10F 19/80

(52) U.S. Cl. CPC H10F 19/807

(57) ABSTRACT

Aspects include: a solar panel having (a) an array of photovoltaic (PV) cells; and (b) a package encapsulating the array of PV cells, and with the top section and the bottom section of the package bonded together at a bonded perimeter of the package to form a hermetic seal around the array of PV cells; wherein (i) the top section of the package includes a glass composition or a glass-ceramic composition; and (ii) the bottom section of the package includes a glass composition, a glass-ceramic composition, or a metal.

### CROSS-REFERENCE TO RELATED APPLICATIONS

This application claims the benefit of priority under 35 U.S.C. § 119 of U.S. Provisional Application No. 63/467,714 filed May 19, 2023, the content of which is incorporated herein by reference in its entirety.

### FIELD OF THE DISCLOSURE

The present disclosure pertains to solar panels and, more specifically, to solar panels with increased recyclable content.

### BACKGROUND

Fossil fuels have been used extensively as a primary source of energy, especially since the start of the industrial revolution in the mid to late 19th century. However, fossil fuels are finite and, when burned to produce heat, produce air pollution and greenhouse gases. To reduce reliance on fossil fuels as an energy source, renewable energy sources such as solar energy and wind energy are being used to generate electrical energy.

Solar energy in particular is energy that can be harnessed from photons that the Sun emits. Solar energy can be harnessed in a variety of ways, such as photovoltaic (PV) cells and solar-thermal. In the case of PV cells, some of the photons that the Sun emits can be absorbed by a semiconducting material of the PV cell. The absorption of the photon excites an electron in the semiconducting material to move from a valence band to a conduction band. The movement of the electron to the conduction band creates an electrical current. The electrical current can be directed to an external circuit that powers electrical devices or is converted to chemical energy within a battery for later use.

Sometimes, an array of PV cells are arranged together in a solar panel. In the solar panel, the PV cells are electrically coupled and encapsulated. The encapsulation protects the array of PV cells from degradation and physical damage. Sometimes, the encapsulant is formed of ethylene-vinyl acetate (EVA) or polyvinyl butyral (PVB). In addition, the solar panel sometimes includes a polymer backing. The polymer backing helps protect the array of PV cells from damage and provides structural rigidity to the solar panel. Further, the solar panel includes a transparent glass or polymer layer on top of the encapsulants.

However, there are problems in that EVA and PVB encapsulants (i) are not easily recyclable after the service life of the solar panel, (ii) degrade under ultraviolet (UV) irradiation from the sun, (iii) provide suboptimal protection from alkali and moisture migration to the PV cells from the glass layer and the external environment respectively, and (iv) provides suboptimal heat transfer from the PV cells to the external environment, which reduces the conversion efficiency of the PV cells. Regarding problem (ii), the addition of UV absorbers and antioxidants to the EVA and PVB encapsulants only prolong the eventual degradation of the polymers while simultaneously attenuating the transmission of the UV light to the PV cells through the encapsulants. Thus, another solution is needed.

### SUMMARY

The present disclosure addresses those problems with a package for the PV cells (i) that are made of recyclable materials such as glass, glass-ceramic, and/or metal that encapsulate the PV cells that are hermetically sealed to prevent moisture migration, (ii) utilize layers of alkali ion resistant materials such as SiO₂ and SiNₓ above and below the PV cells to prevent alkali migration, and (iii) utilizes high surface area bonding and thermal transfer materials between the PV cells and the bottom section of the package to increase heat transfer from the PV cells to the external environment.

According to a first aspect of the present disclosure, a solar panel comprises: (a) an array of photovoltaic (PV) cells, each of the PV cells comprising a top primary surface and a bottom primary surface facing away from the top primary surface; and (b) a package encapsulating the array of PV cells, the package comprising a top section and a bottom section, with the top primary surface of each of the PV cells facing the top section and the bottom primary surface of each of the PV cells facing the bottom section, and with the top section and the bottom section of the package bonded together at a bonded perimeter of the package to form a hermetic seal around the array of PV cells; wherein (i) the top section of the package comprises a glass composition or a glass-ceramic composition; and (ii) the bottom section of the package comprises a glass composition, a glass-ceramic composition, or a metal.

According to a second aspect of the present disclosure, the solar panel of the first aspect is presented, wherein the top region consists essentially of a glass composition or a glass-ceramic composition.

According to a third aspect of the present disclosure, the solar panel of the first aspect is presented, wherein the top region consists of a glass composition or a glass-ceramic composition.

According to a fourth aspect of the present disclosure, the solar panel of the first aspect is presented, wherein the top region comprises the glass composition, and the glass composition comprises soda lime glass with low iron content, a glass composition with low alkali content, or a mechanically advantaged glass composition.

According to a fifth aspect of the present disclosure, the solar panel of any one of the first through fourth aspects is presented, wherein the top section and the bottom section of the package are bonded together at the bonded perimeter via anodic bonding.

According to a sixth aspect of the present disclosure, the solar panel of any one of the first through fourth aspects is presented, wherein the top section and the bottom section of the package are bonded together at the bonded perimeter via laser bonding.

According to a seventh aspect of the present disclosure, the solar panel of any one of the first through fourth aspects is presented, wherein the package further comprises a bonding material bonding the top section and the bottom section of the package together at the bonded perimeter.

According to an eighth aspect of the present disclosure, the solar panel of the seventh aspect is presented, wherein the bonding material is a polymer.

According to a ninth aspect of the present disclosure, the solar panel of the seventh aspect is presented, wherein the bonding material is a glass or a glass-ceramic.

According to a tenth aspect of the present disclosure, the solar panel of any one of the first through fourth aspects is presented, wherein (i) the package further includes a middle section disposed between the top section and the bottom section at the bonded perimeter of the package, and (ii) the top section, the middle section, and the bottom section are bonded together.

According to an eleventh aspect of the present disclosure, the solar panel of the tenth aspect is presented, wherein the top section, the middle section, and the bottom section are anodically bonded together.

According to a twelfth aspect of the present disclosure, the solar panel of any one of the tenth through eleventh aspects is presented, wherein the middle section exhibits a lower glass transition temperature than the top section and the bottom section.

According to a thirteenth aspect of the present disclosure, the solar panel of any one of the first through twelfth aspects is presented, wherein (i) the package further comprises an antireflective coating disposed on a bottom surface of the top section of the package facing the top primary surfaces of the PV cells, and (ii) the antireflective coating comprises at least one layer of SiO₂ or SiNₓ.

According to a fourteenth aspect of the present disclosure, the solar panel of any one of the first through thirteenth aspects further comprises an inert gas disposed between the top section and the bottom section of the package and within the bonded perimeter of the package.

According to a fifteenth aspect of the present disclosure, the solar panel of any one of the first through fourteenth aspects is presented, wherein each of the PV cells comprises a crystalline silicon wafer.

According to a sixteenth aspect of the present disclosure, the solar panel of any one of the first through fifteenth aspects further comprises a layer of SiO₂ or SiNₓ disposed between the bottom primary surfaces of the PV cells and a top surface of the bottom section of the package.

According to a seventeenth aspect of the present disclosure, the solar panel of any one of the first through sixteenth aspects further comprises a thermally conductive suspension disposed between the bottom primary surface of each of the PV cells and the bottom section of the package; wherein, the thermally conductive suspension comprises an oil, a surfactant, and inorganic filler that increases the thermal conductivity of the thermally conductive suspension relative to the oil alone.

According to an eighteenth aspect of the present disclosure, the solar panel of any one of the first through seventeenth aspects is presented, wherein each PV cell is bonded to the bottom section of the package with a glass composition, a glass-ceramic composition, anodic bonding, laser bonding, or a thermally conductive bonding material.

According to a nineteenth aspect of the present disclosure, the solar panel of any one of the first through eighteenth aspects is presented, wherein (i) adjacent PV cells are in electrical communication through the incorporation of solder, (ii) the solder comprises one or more electrically conductive metals, and (iii) the solder is substantially free of cadmium, lead, mercury, and hexavalent chromium.

According to a twentieth aspect of the present disclosure, the solar panel of any one of the first through nineteenth aspects is presented, wherein (i) adjacent PV cells are in electrical communication through the incorporation of conductive paste, (ii) the conductive paste comprises a mixture of electrically conductive metal particles and a binder material, and (iii) the electrically conductive metal particles are substantially free of cadmium, lead, mercury, and hexavalent chromium.

According to a twenty-first aspect of the present disclosure, the solar panel of any one of the first through twentieth aspects is presented, wherein (i) the bottom section of the package further comprises wells to accommodate each of the PV cells and electrical current collection and transmission components; and (ii) a top surface of the bottom section within each of the wells for the PV cells is planar.

According to a twenty-second aspect of the present disclosure, the solar panel of any one of the first through twenty-first aspects further comprises: electrical current collection and transmission components comprising wiring nets made of cut sheets of coated copper.

According to a twenty-third aspect of the present disclosure, the solar panel of any one of the first through twenty-second aspects further comprises stamped flat springs that at least partially secure the PV cells within the package.

According to a twenty-fourth aspect of the present disclosure, the solar panel of any one of the first through twenty-third aspects further comprises a backing supporting the package, the backing comprising a sheet or film of metal.

According to a twenty-fifth aspect of the present disclosure, the solar panel of the twenty-fourth aspect is presented, wherein the sheet or film of metal of the backing comprises aluminum with a surface layer of aluminum oxide.

According to a twenty-sixth aspect of the present disclosure, the solar panel of any one of the twenty-fourth through twenty-fifth aspects is presented, wherein the backing is anodically bonded to the package.

According to a twenty-seventh aspect of the present disclosure, the solar panel of any one of the twenty-fourth through twenty-sixth aspects further comprises a thermal transfer fluid disposed between the backing and the package.

According to a twenty-eighth aspect of the present disclosure, the solar panel of any one of the twenty-fourth through twenty-seventh aspects further comprises at least one of a heat sink and a stiffener integrated with the backing.

According to a twenty-ninth aspect of the present disclosure, the solar panel of the twenty-eight aspect is presented, wherein the at least one heat sink is directly bonded to the backing.

According to a thirtieth aspect of the present disclosure, any one of the first through twenty-ninth aspects are presented, wherein the bottom section of the package comprises a glass composition that has a coefficient of thermal expansion that is within a range of from 1×10⁻⁶ per °C to 5×10⁻⁶ per °C.

According to a thirty-first aspect of the present disclosure, the thirtieth aspect is presented, wherein the PV cells are bonded to the bottom section of the package with a glass composition or a glass-ceramic composition that has a coefficient of thermal expansion that is also within a range of from 1×10⁻⁶ per °C to 5×10⁻⁶ per °C.

According to a thirty-second aspect of the present disclosure, the solar panel of any one of the first through thirty-first aspects, wherein the solar panel has an asymmetric construction where the top section and the bottom section of the package have at least one of different compositions, different compressive stress profiles, different thicknesses, and non-mirror image spatial relationships relative to the array of PV cells.

According to a thirty-third aspect of the present disclosure, a solar panel comprises: (a) an array of photovoltaic (PV) cells, each of the PV cells comprising a top primary surface and a bottom primary surface facing away from the top primary surface; (b) a package encapsulating the array of PV cells, the package comprising a top section comprising a glass composition and a bottom section, with the top primary surface of each of the PV cells facing the top section and the bottom primary surface of each of the PV cells facing the bottom section, and with the top section and the bottom section of the package bonded together at a bonded perimeter of the package to form a hermetic seal around the array of PV cells; (c) a layer of SiO₂ or SiNₓ disposed between the bottom primary surfaces of the PV cells and a top surface of the bottom section of the package; and (d) an antireflective coating disposed on a bottom surface of the top section of the package facing the top primary surfaces of the PV cells, the antireflective coating comprises at least one layer of SiO₂ or SiNₓ.

According to a thirty-fourth aspect of the present disclosure, a solar panel comprises: (a) an array of photovoltaic (PV) cells, each of the PV cells comprising a top primary surface and a bottom primary surface facing away from the top primary surface; (b) a package encapsulating the array of PV cells, the package comprising a top section comprising a glass composition and a bottom section, with the top primary surface of each of the PV cells facing the top section and the bottom primary surface of each of the PV cells facing the bottom section, and with the top section and the bottom section of the package bonded together at a bonded perimeter of the package to form a hermetic seal around the array of PV cells; (c) a backing supporting the package, the backing comprising a sheet or film of metal; and (d) a thermal transfer fluid disposed between the backing and the package.

According to a thirty-fifth aspect of the present disclosure, the solar panel of the thirty-fourth aspect further comprises a heat sink integrated formed with the backing via extrusion of a metal.

According to a thirty-sixth aspect of the present disclosure, the solar panel of any one of the thirty-fourth through thirty-fifth aspects further comprises a thermally conductive suspension disposed between the bottom primary surface of each of the PV cells and the bottom section of the package; wherein, the thermally conductive suspension comprises an oil, a surfactant, and inorganic filler that increases the thermal conductivity of the thermally conductive suspension relative to the oil alone.

Additional features and advantages will be set forth in the detailed description which follows and will be readily apparent to those skilled in the art from that description or recognized by practicing the embodiments as described herein, including the detailed description which follows, the claims, as well as the appended drawings.

It is to be understood that both the foregoing general description and the following detailed description are merely exemplary and are intended to provide an overview or framework to understanding the nature and character of the disclosure as it is claimed.

The accompanying drawings are included to provide a further understanding of principles of the disclosure, and are incorporated in, and constitute a part of, this specification. The drawings illustrate one or more embodiment(s) and, together with the description, serve to explain, by way of example, principles and operation of the disclosure. It is to be understood that various features of the disclosure disclosed in this specification and in the drawings can be used in any and all combinations. By way of non-limiting examples, the various features of the disclosure may be combined with one another according to the following aspects.

### BRIEF DESCRIPTION OF THE DRAWINGS

These and other features, aspects and advantages of the present disclosure are better understood when the following detailed description of the disclosure is read with reference to the accompanying drawings, in which:

FIG. 1 is a perspective view of a solar array including solar panels of the present disclosure;

FIG. 2 is an exploded perspective view of the solar panel of FIG. 1, illustrating the solar panel including an array of photovoltaic cells (PV cells) and a package encapsulating the PV cells;

FIG. 3 is a cross-sectional view of the solar panel of FIG. 1, illustrating the package including a top section and a bottom section that are bonded together at a bonded perimeter and together form a cavity within which the PV cells are disposed;

FIG. 4 is a magnified view of area IV of FIG. 3, illustrating a bonding material bonding the top section and the bottom section of the package together at the bonded perimeter;

FIG. 5 is a magnified view of area V of FIG. 3, illustrating an alternative embodiment of the solar panel of FIG. 1 where a middle section laterally defines the cavity and is bonded between the top section and the bottom section at the bonded perimeter;

FIG. 6 is a magnified view of area VI of FIG. 3, illustrating an antireflective coating disposed on a bottom surface of the top section of the package;

FIG. 7 is a magnified view of area VII of FIG. 3, illustrating the bottom section forming a well within which one of the PV cells is disposed and a stamped flat spring depending downward from the top section and applying a force upon the PV cell to maintain the PV cell in position within the well;

FIG. 8 is a magnified but perspective view of area VIII of FIG. 3, illustrating adjacent wells within which adjacent PV cells are disposed and electrical current collection and transmission components 80 electrically joining the PV cells;

FIG. 9 is the same view as FIG. 8 but this time with the PV cells shown in phantom to illustrate that the bottom section of the package at the wells provides a top surface that is planar; and

FIG. 10 is a perspective view of area X of FIG. 3, illustrating a thermal transfer fluid disposed between the bottom section of the package and a backing that provides structural support to the package.

### DETAILED DESCRIPTION

In the following detailed description, for purposes of explanation and not limitation, example embodiments disclosing specific details are set forth to provide a thorough understanding of various principles of the present disclosure. However, it will be apparent to one having ordinary skill in the art, having had the benefit of the present disclosure, that the present disclosure may be practiced in other embodiments that depart from the specific details disclosed herein. Moreover, descriptions of well-known devices, methods and materials may be omitted so as not to obscure the description of various principles of the present disclosure. Finally, wherever applicable, like reference numerals refer to like elements.

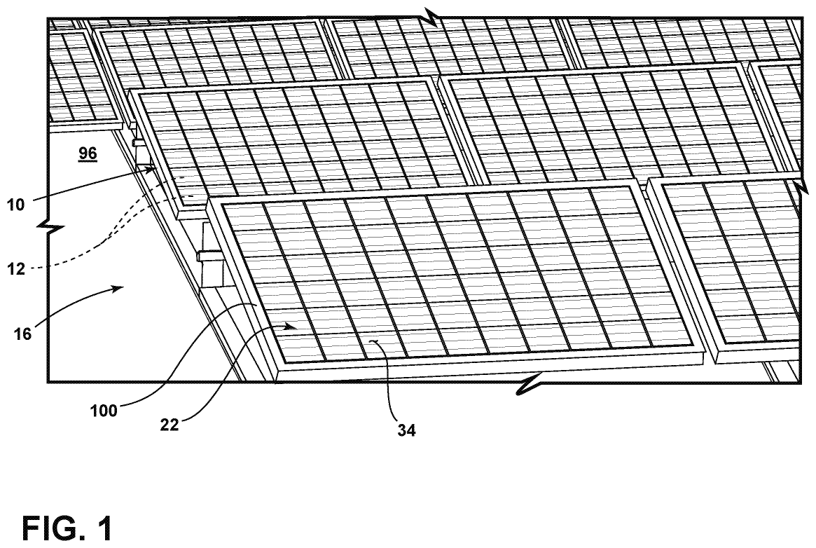

Referring to FIGS. 1-3, a solar panel 10 includes an array of photovoltaic cells (PV cells) 12 and a package 14 encapsulating the array of PV cells 12. The array of PV cells 12 can be any number of PV cells 12. For example, the array of PV cells 12 can be within a range of 20 to 80 PV cells 12, such as from 60 to 72 PV cells 12. The solar panel 10 can be part of a solar array 16 that includes a grouping of more than one of the solar panels 10.

Each PV cell 12 includes a top primary surface 18 and a bottom primary surface 20. The top primary surface 18 is positioned to face the Sun. For example, the semiconductor material that converts sunlight into electricity is exposed to the sunlight at the top primary surface 18. The bottom primary surface 20 faces away from the top primary surface 18. The top primary surface 18 and the bottom primary surface 20 can be generally planar.

The package 14 that encapsulates the array of PV cells 12 includes a top section 22 and a bottom section 24. The top section 22 is configured to face the Sun. For example, the top section 22 is sufficiently transparent to desired wavelengths of electromagnetic radiation from the Sun to permit the array of PV cells 12 to generate electricity from the desired wavelengths of electromagnetic radiation transmitting through the top section 22. The top primary surface 18 of each of the PV cells 12 faces the top section 22 of the package 14. The bottom primary surface 20 of each of the PV cells 12 faces the bottom section 24 of the package 14.

The top section 22 and the bottom section 24 of the package 14 are bonded together at a bonded perimeter 26 of the package 14. For example, in embodiments, the bottom section 24 includes a recessed portion 28 and a raised portion 30 relative to the recessed portion 28 disposed around the recessed portion 28. The recessed portion 28 and the raised portion 30 together form a cavity 32. The array of PV cells 12 are disposed within the cavity 32. The top section 22 and the raised portion 30 of the bottom section 24 are bonded together at the bonded perimeter 26. The bonded perimeter 26 laterally surrounds the cavity 32.

The top section 22 of the package 14 comprises, consists essentially of, or consists of a glass composition or a glass-ceramic composition. A suitable glass composition is a soda lime glass, and in particular soda lime glass with a low iron content. “Soda lime glass with a low iron content” means that the soda lime glass contains less than 200 ppm Fe₂O₃ as measured using X-ray fluorescence (XRF). Such soda lime glass is highly transparent to typical wavelengths of electromagnetic radiation from the Sun that the PV cells 12 utilize to convert to electricity. Reducing the iron and iron oxide content increases the transparency of the soda lime glass. In addition, the soda lime glass can be thermally tempered. Further, soda lime glass is easily recyclable. Another suitable glass composition is one with low alkali content, meaning that the total concentration of alkali oxides Li₂O, Na₂O, and K₂O is less than 0.1 mol %. Other suitable glass compositions include mechanically advantaged glass compositions, meaning that the glass has been mechanically strengthened via thermal tempering, chemical strengthening (e.g., ion-exchange), or lamination. Regarding lamination, the glass is strengthened by means of creating a 3-layer glass construction where the outer glass layers have a different composition having a lower coefficient of thermal expansion (CTE) than a middle glass layer in the laminate, so that upon cooling, the middle layer of the laminate contracts more, placing the outer layers of the glass in a state of compressive stress. Other suitable glass compositions include borosilicate glass compositions and aluminosilicate glass compositions, among others, especially those that can be chemically or thermally strengthened. Suitable glass-ceramic compositions include lithium-aluminosilicate glass-ceramic compositions, beta-quartz glass-ceramic compositions, and spinel glass-ceramic compositions, among others. In embodiments, the top section 22 has at least one region of compressive stress, which can be imparted via ion-exchange or thermal tempering, such as contiguous with a top surface 34 thereof.

The bottom section 24 of the package 14 comprises, consists essentially of, or consists of a glass composition, a glass-ceramic composition, or a metal. Any of the glass compositions or glass-ceramic compositions discussed for the top section 22 of the package 14 are suitable for the bottom section 24 of the package 14. An example metal is aluminum, although others are envisioned such as steel and various other alloys. The recessed portion 28 and the raised portion 30 can be formed via etching of the glass composition or glass-ceramic composition of the bottom section 24. In embodiments where the bottom section 24 is made of a metal, the bottom section 24 is electrically isolated from the PV cells 12. For example, a top surface 66 of the bottom section 24 can be anodized and/or an alumina ceramic sheet or ribbon can be disposed between the top surface 66 of the bottom section 24 and the PV cells 12, to electrically isolate the bottom section 24 of metal from the PV cells 12.

In embodiments, the top section 22 and the bottom section 24 of the package 14 are bonded together at the bonded perimeter 26 via anodic bonding. To anodic bond the top section 22 and the bottom section 24 together, the top section 22 and the bottom section 24 are brought together in the desired orientation, the temperature of the top section 22 and the bottom section 24 is increased to a working temperature for anodic bonding, and an electrical potential is applied across the top section 22 and the bottom section 24, one of which is made negatively charged. The negatively charged component attracts positive ions from the other component. The accumulation of positive ions at the interface between the top section 22 and the bottom section 24 causes chemical reactions that result in the formation of covalent bonds at the interface of the top section 22 and the bottom section 24. To facilitate the anodic bond, the glass composition of the top section 22 can include positive ions such as alkali ions (e.g., Li⁺, Na⁺, K⁺). Subjecting the top section 22 to an ion-exchange process to impart the aforementioned one or more regions of compressive stress can be utilized as well to saturate a bottom surface 36 of the top section 22 with the positive ions that, in turn, participate in the anodic bonding process. Anodic bonding can be used to bond the top section 22 and the bottom section 24 together regardless of whether the bottom section 24 has a glass composition, a glass-ceramic composition, or is metal. In instances where the top section 22 has a glass composition and the bottom section 24 is metal, the metal is negatively charged during the anodic bonding process. The negatively charged metal attracts the positive alkali ions from the glass composition of the top section 22. The presence of the alkali ions causes reactions to occur with the metal of the bottom section 24, and the reactions result in the creation of covalent bonds at the interface between the glass composition or glass-ceramic composition of the top section 22 and the metal of the bottom section 24.

In embodiments, the top section 22 and the bottom section 24 are bonded together at the bonded perimeter 26 via laser bonding, particularly when both the top section 22 and the bottom section 24 include a glass composition or a glass-ceramic composition. For example, a focus of a laser beam can be positioned at the interface of the top section 22 and the bottom section 24 where the bonded perimeter 26 is to be. The top section 22, the bottom section 24, or both the top section 22 and the bottom section 24 at or near the interface between the top section 22 and the bottom section 24 absorbs at least a portion of the energy from the laser beam. The absorbed energy causes the material to increase in temperature that is sufficient to soften the materials at the interface and induce diffusion between the two materials. The top section 22 and the bottom section 24 then cool with a bond having been formed where the interface was. A third material that is a better absorber of the wavelength of the laser beam than the top section 22 and the bottom section 24 can be disposed therebetween. In such instances, the third material (e.g., a thin film of metal) absorbs the laser energy, heats up, and diffuses into both the top section 22 and the bottom section 24 and thus bonds the top section 22 and the bottom section 24 together.

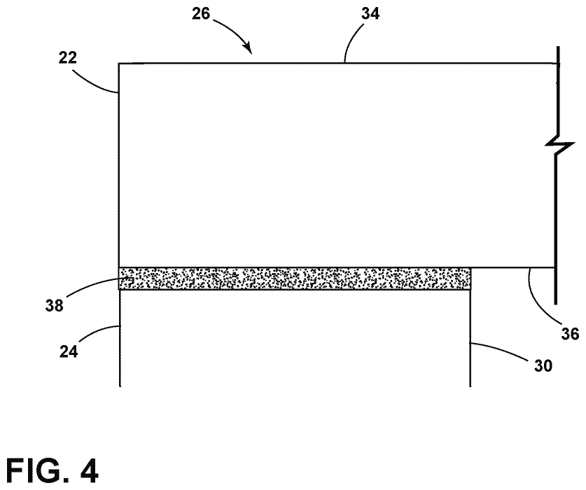

In embodiments, referring now to FIG. 4, the package 14 includes a bonding material 38 that bonds the top section 22 and the bottom section 24 of the package 14 together at the bonded perimeter 26. The bonding material 38 can be any material that bonds the top section 22 and the bottom section 24 together while providing a hermetic seal within the cavity 32. “Hermetic seal” for purposes of this disclosure means that the package 14 exhibits a leak rate of less than or equal to 1×10⁻⁸ atm cm³/s during a helium gas leak test conducted under International Electrotechnical Commission (IEC) standard 60068-2-17. For example, the bonding material 38 can be a polymer. The polymer can be applied as a thermosetting resin that is subsequently cured into the polymer that bonds the top section 22 and the bottom section 24. Suitable resins include epoxy resins, a silicone resins, polyurethan resins, and acrylic resins, and so on. Curing of the resins could be initiated via application of light of a suitable wavelength transmitted through the top section 22 or via application of heat, among other ways. Alternatively, the polymer can be applied via injection molding between the top section 22 and the bottom section 24. A suitable injection molded polymer is a polyaryletherketone (PAEK), such as polyetheretherketone (PEEK), polyetherketone (PEK), and polyetherketoneketone (PEKK).

In embodiments, the bonding material 38 is a glass or a glass-ceramic. For example, glass frit can be applied between the top section 22 and the bottom section 24 where the bonded perimeter 26 is to be. The glass frit may have a glass transition temperature (Tg) that is lower than 500° C., or lower than the Tg of a soda lime silicate glass. The glass frit may comprise multiple components, for example a low-Tg glass component and a filler particle component, where the filler particle may be a glass or ceramic with high Tg or high melting temperature, where the filler particle may be added to adjust the effective coefficient of thermal expansion (CTE) of the glass frit mixture. The glass frit is then heated to at least the softening point of the low-Tg glass component of the frit. The melted glass frit bonds to the top section 22 and the bottom section 24. Upon cooling, what was the glass frit resolidifies as either a glass or a glass-ceramic, depending on the composition of the glass frit utilized. Potentially preferred bonding materials in edge sealing applications (where the bonding material glass is not directly bonded to silicon) may include glass compositions having a CTE in the range of 7 to 12×10⁻⁶ per ° C., in order to have a CTE that is in the same range as soda lime silicate glass. Such CTE can be achieved by adjusting the ratio of low-Tg glass to filler particles, as further described in Morena, R. “Phosphate glasses as alternatives to Pb-based sealing frits.” Journal of Non-Crystalline Solids 263 (2000): 382-387, and in U.S. Pat. No. 5,246,890 (Aitken et al.), incorporated here by reference.

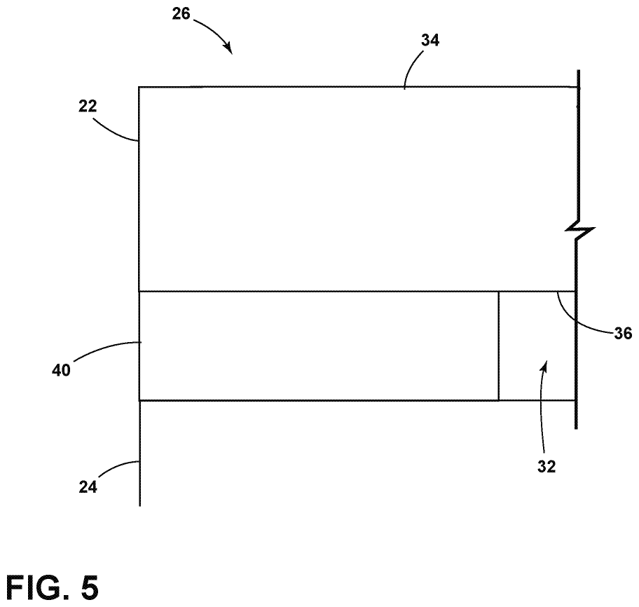

In embodiments, referring to FIG. 5, instead of the bonding material 38, the package 14 further includes a middle section 40 disposed between the top section 22 and the bottom section 24 at the bonded perimeter 26 of the package 14. The top section 22, the middle section 40, and the bottom section 24 are bonded together at the bonded perimeter 26 to hermetically seal the cavity 32 disposed between the top section 22 and the bottom section 24. Note that when the middle section 40 is utilized, the bottom section 24 need not have the recessed portion 28 and the raised portion 30 to form the cavity 32. Rather, the middle section 40 separates the top section 22 from the bottom section 24 and laterally frames the cavity 32.

The middle section 40 can be bonded to both the top section 22 and the bottom section 24 in any of the manners previously described, such as anodic bonding, laser bonding, glass frit bonding, bonding with a bonding material 38, and so on. In embodiments, all three of the top section 22, the middle section 40, and the bottom section 24 are glass compositions or glass-ceramic compositions, and the middle section 40 exhibits a lower glass transition temperature than the top section 22 and the bottom section 24.

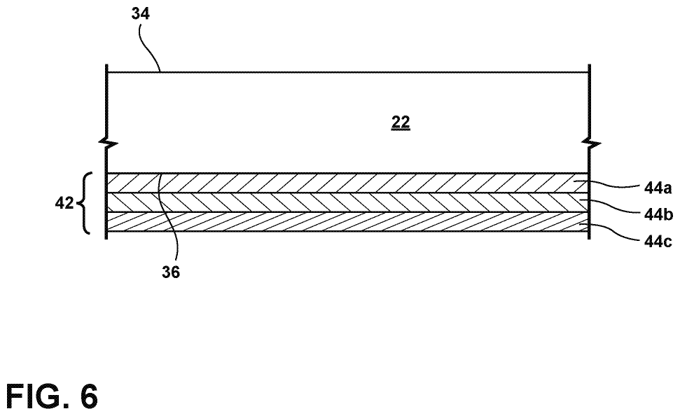

Referring now to FIG. 6, in embodiments, the package 14 further includes an antireflective coating 42. The antireflective coating 42 can be disposed on the top section 22. For example, the antireflective coating 42 can be disposed on the top surface 34 (e.g., the Sun-facing surface) of the top section 22. In addition, or in the alternative, the antireflective coating 42 can be disposed on the bottom surface 36 of the top section 22, such as the portion of the bottom surface 36 exposed to the cavity 32 or otherwise facing the top primary surfaces 18 of the PV cells 12. The antireflective coating 42 reduces the amount of sunlight that the top section 22 reflects away from the PV cells 12. Thus, the antireflective coating 42 increases the amount of sunlight that the PV cells 12 convert into electricity. Antireflective coatings 42 can be disposed on both the top surface 34 and the bottom surface 36 of the top section 22.

The antireflective coating 42 can include layers 44a, 44b, 44c, . . . 44n of materials having different compositions that exhibit different indices of refraction. Such configurations rely on principles of destructive interference to reduce the amount of light that the top section 22 reflects away from the PV cells 12. Thicknesses of the layers 44a, 44b, 44c, . . . 44n can be individually tailored to minimize reflection of a desired wavelength of electromagnetic radiation and/or to maximize transmittance of the desired wavelength of electromagnetic radiation through the top section 22. The antireflective coating 42 can include at least one layer of SiO₂. The antireflective coating 42 can include at least one layer of SiNₓ. Many other compositions for the layers 44a, 44b, 44c, . . . 44n are envisioned.

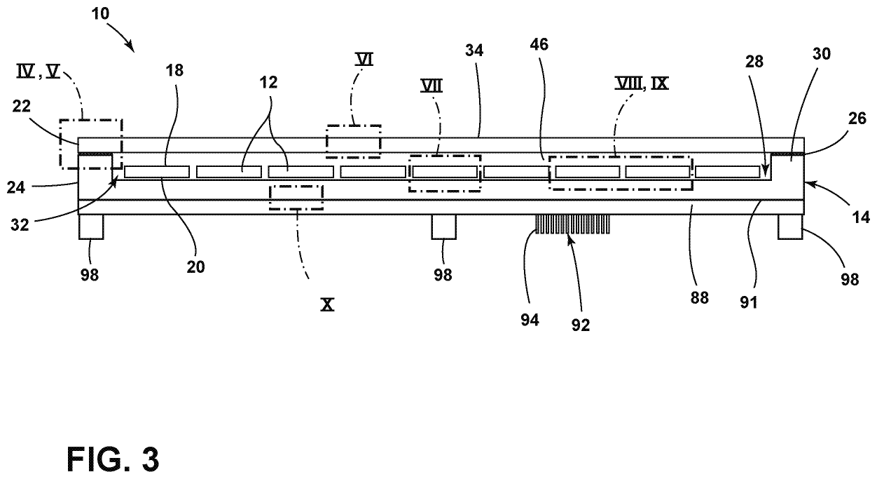

Referring back to FIG. 3, as mentioned, the package 14 is hermetically sealed around the cavity 32 where the PV cells 12 are disposed. In embodiments, the solar panel 10 further includes an inert gas 46 disposed within the cavity 32 around the PV cells 12. For example, the inert gas 46 is disposed between the top section 22 and the bottom section 24 of the package 14 and within the bonded perimeter 26 of the package 14. The PV cells 12 include semiconductor materials, such as silicon. Exposure of the semiconductor materials to oxygen and moisture can cause degradation of the semiconductor materials. As the semiconductor materials degrade, the efficiency at which the PV cells 12 convert sunlight into electricity diminishes. Evacuating the cavity 32 within which the PV cells 12 are disposed and inserting inert gas 46 prevents such problems. The inert gas 46 can be argon, nitrogen, a mixture of argon and nitrogen, among other options.

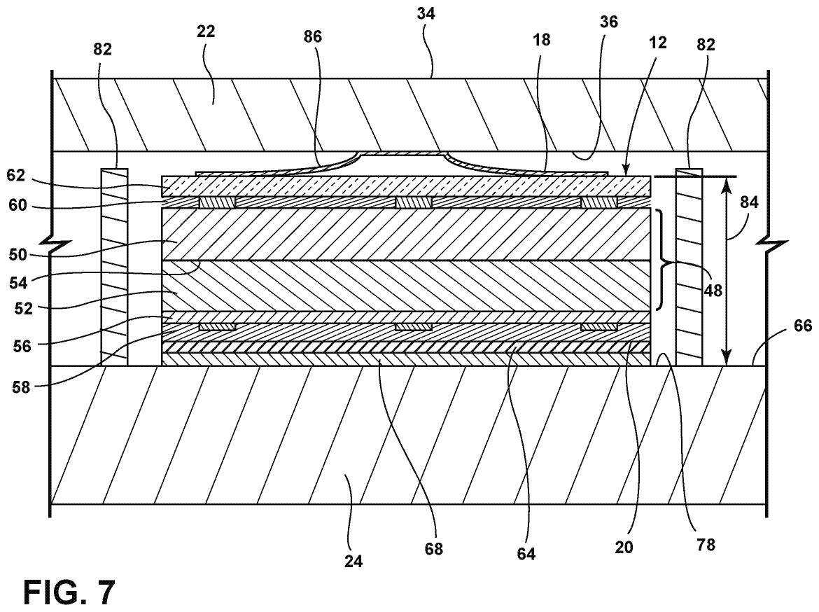

Referring now to FIG. 7, in embodiments, each of the PV cells 12 includes a silicon wafer 48. The silicon wafer 48 can be made of amorphous silicon or crystalline silicon. The crystalline silicon wafer 48 can be monocrystalline or polycrystalline and the term “crystalline” is meant to include both monocrystalline and polycrystalline types. The silicon wafer 48 has regions 50, 52, one of which is an n-type region and the other of which is a p-type region, and a p-n junction 54 therebetween. The PV cells 12 can include additional layers between the silicon wafer 48 and the bottom section 24 of the package 14, such as a metal layer 56 below the silicon wafer 48 and a backsheet 58 below the metal layer 56. The PV cells 12 can include further layers above the silicon wafer 48, such as an antireflective coating 60 and a glass layer 62.

In embodiments, the solar panel 10 further includes a barrier layer 64 disposed between the bottom primary surface 20 of the PV cell 12 and the top surface 66 of the bottom section 24 of the package 14. The barrier layer 64 can be any material that blocks diffusion of alkali ions (e.g., Na⁺) from the bottom section 24 of the package 14 to the to the PV cell 12. The presence of alkali ions on the surface of the silicon wafer 48 of the PV cell 12 can create a positive charge imbalance. The positive charge imbalance deteriorates performance of the PV cell 12, and the deteriorated performance is sometimes referred to as potential induced degradation (PID). In embodiments, the barrier layer 64 is SiO₂ or SiNₓ. Other materials are envisioned. It is worth noting that the antireflective coating 42 disposed on the top section 22 between the top section 22 and the PV cell 12, typically including one or more layers of SiO₂ and/or SiNₓ serves the same function as the barrier layer 64 of preventing PID.

In embodiments, the solar panel 10 further includes a thermally conductive suspension 68 disposed between the bottom primary surface 20 of each of the PV cells 12 and the bottom section 24 of the package 14. The thermally conductive suspension 68 transfers heat from the PV cell 12 to the bottom section 24 of the package 14. In general, the greater the transfer of heat out of the PV cell 12, the greater the efficiency of the PV cell 12. The thermally conductive suspension 68 can include an oil, a surfactant, and an inorganic filler. The inorganic filler increases the thermal conductivity of the thermally conducive suspension relative to the oil alone. Suitable inorganic fillers include boron nitride (BN), aluminum oxide (Al₂O₃), and silicon carbide (SiC), among other options. The surfactant stabilizes the suspension and permits the suspension to be cleaned with an organic detergent during recycling of the solar panel 10. Suitable surfactants include sodium dodecylbenzenesulfonate but others are envisioned, including plant-based surfactants (e.g., coco glucoside, lauryl glucoside, decyl glucoside, sodium lauryl sulfoacetate, and sodium cocoamphoacetate).

In embodiments, each PV cell 12 is bonded to the bottom section 24 of the package 14. Any of the ways discussed above to bond the top section 22 and the bottom section 24 of the package 14 together would be appropriate to bond the PV cells 12 to the bottom section 24 of the package 14. For example, glass frit bonding, anodic bonding, laser bonding, and a bonding material could be utilized. In embodiments where the bottom section 24 of the package 14 is a glass layer bonded to the PV cell 12, it may be preferred to use a glass composition for the bottom section 24 that is substantially CTE-matched to silicon. Examples of glasses with a close expansion match to silicon (e.g., CTE that is within a range of from 1×10⁻⁶ per ° C. to 5×10⁻⁶ per ° C.) glasses include alkaline-earth aluminoborosilicate glasses, which may be alkali-free, including glasses such as Corning Eagle XG.

In the instance of a glass frit bonding, the result is a layer of a glass composition or a glass-ceramic composition bonding each PV cell 12 to the bottom section 24. The glass frit can be thermally conductive, such as a glass frit material mixed with thermally conductive materials (e.g. carbon particles, carbon fibers, or alumina particles). Examples of such “bonding glass” compositions which may be used in glass frits (either to bond the bottom section 24 directly to the PV cells 12, or to form glass-to-glass or glass-to-metal bonds around the bonded perimeter 26 of the package 14) may include tin silicates, tin phosphates, tin zinc phosphates, or tin borophosphates, all of which may include additions of ZnO or Al₂O₃, and all of which may be lead-free. Examples of such frit compositions that can be substantially expansion matched to silicon (e.g. CTE=1 to 5×10⁻⁶ per ° C.) can be found in: Morena, R. “Phosphate glasses as alternatives to Pb-based sealing frits,” Journal of Non-Crystalline Solids 263 (2000) 382-387, incorporated herein by reference. Such frits could be advantageously used to bond the PV cells 12 of silicon to the bottom section 24 of glass and be substantially expansion matched to silicon to have a CTE within a range of from 1×10⁻⁶ per ° C. to 5×10⁻⁶ per ° C. In embodiments, the frits (and the glass or glass-ceramic composition resulting therefrom) have a coefficient of thermal expansion that is lower than the coefficient of thermal expansion than the bottom section of the package.

In embodiments, the solar panel 10 may comprise an asymmetric construction. There are multiple forms in which the solar panel 10 construction may be asymmetric. These asymmetric forms of the solar panel 10 may include one or more of the following designs, which may also be used in combination. First, the PV cells 12 can be directly bonded to the bottom section 24 which comprises metal or glass, using any of the above methods, e.g., anodic bonding or glass frit bonding, and the PV cells 12 are not directly bonded to the top section 22. In this embodiment, there may be an air gap, inert gas, or a transparent polymer bonding layer (which may be removable or recyclable) between the PV cells 12 and the top section 22, where the top section 22 is preferably a glass. Such a construction can improve thermal energy removal from the PV cells 12, while also providing high protection from hail or other impacts on the top section 22. Second, the top section 22 and bottom section 24 may both comprise a glass, where the top section 22 has a different thickness than the bottom section 24. In some cases, it is preferred that the top section 22 has a greater thickness, e.g. 2-3.5 mm, to withstand hail impacts, while the bottom section 24 may have a lower thickness, e.g. 0.1-2 mm, to reduce weight, cost, or improve thermal management. Such solar panels 10 may also be bifacial, e.g. able to harvest energy from light incident on both sides of the solar panel 10, due to the transparency of glass forming both the top section 22 and the bottom section 24. Either or both of the top section 22 and the bottom section 24 may be thermally, chemically, or laminate strengthened, as described above. Third, the top section 22 and the bottom section 24 can both comprise glass, but the top section 22 and the bottom section 24 glasses have a different composition, a different construction, different stress levels, or are strengthened by different methods. For example, the glass of the top section 22 may be an alkali-containing glass or a laminated glass that is strengthened, and the glass of the bottom section 24 may be an alkali-free glass that has a CTE close to that of silicon, where the bottom section 24 is directly bonded to the PV cell 12, and the top section 22 is not directly bonded to the PV cell 12. In some embodiments like these, the top section 22 may be a laminate-strengthened glass that also has a controlled average CTE, that may be either lower than soda-lime glass or close to that of silicon, e.g. a CTE in the range of 1 to 50×10⁻⁶ per ° C. In general, the solar panel has an asymmetric construction when the top section 22 and the bottom section 22 have at least one of different compositions, different compressive stress profiles, different thicknesses, and non-mirror image spatial relationships relative to the array of PV cells 12.

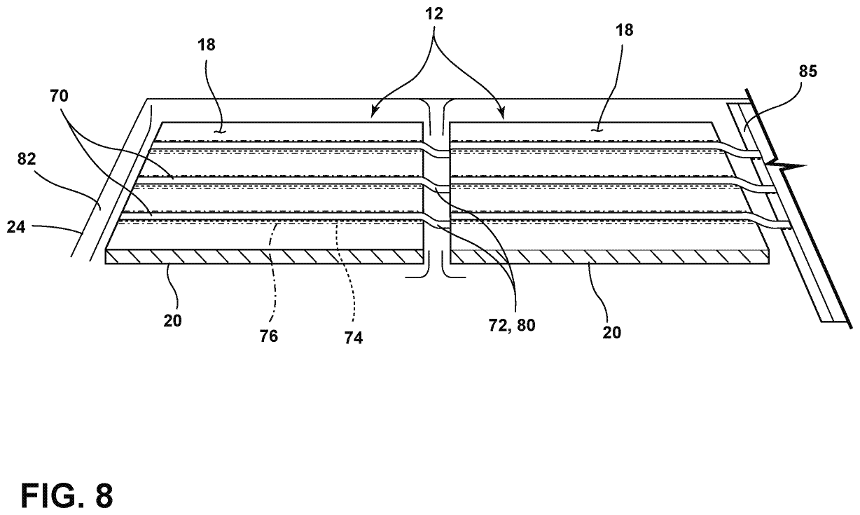

Referring additionally to FIG. 8, adjacent PV cells 12 are in electrical communication with each other. For example, each PV cell 12 includes busbars 70 available for electrical contact at the top primary surface 18 and the bottom primary surface 20 of the PV cell 12. Tab wire 72 can be utilized to electrically connect one of the busbars 70 available at the top primary surface 18 of one PV cell 12 to one of the busbars 70 available at the bottom surface 36 of an adjacent PV cell 12. The tab wire 72 can be connected to the busbar 70 by soldering the tab wire 72 and the busbar 70 together with solder 74. In short, adjacent PV cells 12 are in electrical communication through the incorporation of solder 74. The solder 74 includes one or more electrically conductive metals. In embodiments, the solder 74 utilized to place adjacent PV cells 12 in electrical communication with each other is substantially free of cadmium, lead, mercury, and hexavalent chromium (e.g., Cr(VI)). “Substantially free” means that those materials are not purposefully included in the solder 74, but may be present as trace materials. Suitable metals for the solder 74 include tin-silver-copper alloy, tin-copper alloy, tin-silver alloy, bismuth-tin-silver alloy, and zinc-aluminum alloy, among others.

In embodiments, adjacent PV cells 12 are in electrical communication with each other through the incorporation of conductive paste 76. The conductive paste 76 can be utilized as a replacement for the solder 74 or in addition to the solder 74. For example, tab wires 72 can be attached to the busbars 70 of adjacent PV cells 12 with the conductive paste 76. The conductive paste 76 includes a mixture of electrically conductive metal particles and a binder material. In embodiments, the conductive paste 76 is substantially free of cadmium, lead, mercury, and hexavalent chromium (e.g., Cr(VI)). Suitable metals for the conductive paste 76 include tin, silver, or copper, or alloys thereof, among other options. “Substantially free” means that the mentioned elements are not purposefully added to the material at issue (e.g., the conductive paste 76) but may be present in a trace amount (e.g., less than 100 ppm).

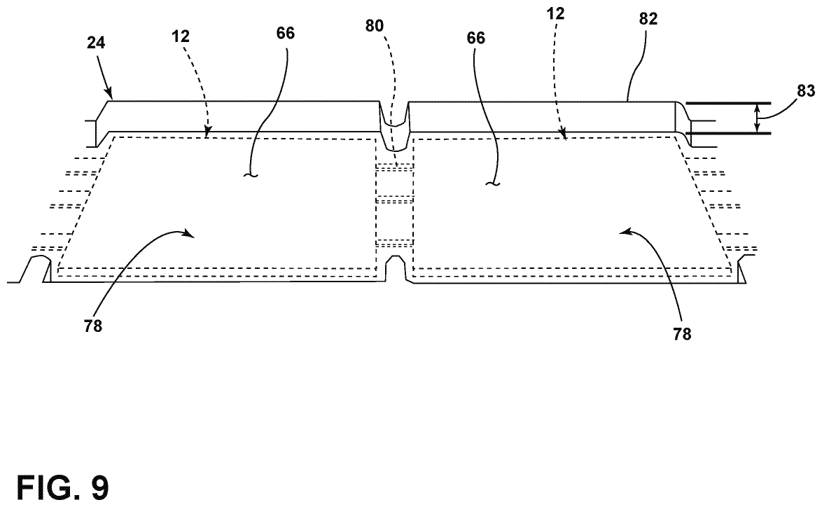

Referring additionally to FIG. 9, in embodiments, the package 14 further includes wells 78 to accommodate each of the PV cells 12 and electrical current collection and transmission components 80. For example, the wells 78 can be formed into (e.g., etched into or molded) or otherwise disposed at the bottom section 24 of the package 14. The wells 78 accommodate each of the PV cells 12 and electrical current collection and transmission components 80, such as the tab wires 72 connecting adjacent PV cells 12. The top surface 66 of the bottom section 24 within each of the wells 78 for the PV cells 12 can be planar. The top surface 66 being planar within the wells 78 assists in bonding the PV cells 12 to the bottom section 24 of the package 14 and facilitates thermal transfer from the PV cells 12 to the bottom section 24 of the package 14. As an alternative or addition to the wells 78 formed into the bottom section 24 of the package, wells 78 (not separately illustrated) can be formed into the bottom surface 36 of the top section 22 of the package 14. The top section 22 can be patterned via molding or etching to accommodate the PV cells 12 and electrical current collection and transmission components 80.

Mesas 82 separate adjacent wells 78. The mesas 82 can have a height 83 from the top surface 66 of the bottom section 24 of the package 14 beneath the PV cells 12 that is greater than a height 84 of the PV cells 12. The difference between the heights 83, 84 helps maintain separation between the top primary surface 18 of the PV cells 12 and the top section 22 of the package 14 and thereby limit alkali ion migration from the top section 22 of the package 14 to the PV cells 12. Etching can also be utilized to pattern the package 14 to accommodate wave-soldering of PV cells 12 and other electrical current collection and transmission components 80 of the solar panel 10.

The electrical current collection and transmission components 80 can further include busbars 85 that connect adjacent PV cells 12 near the bonded perimeter 26 of the package 14. The busbars 85 can be wiring nets made of cut sheets of metal, such as copper or coated copper.

In embodiments, the solar panel 10 further includes stamped flat springs 86 that at least partially secure the PV cells 12 within the package 14. For example, the stamped flat springs 86 can be secured to the bottom surface 36 of the top section 22 of the package 14. The stamped flat springs 86 extend down toward the bottom section 24 of the package 14. The stamped flat springs 86 are positioned to push against the top primary surface 18 of each of the PV cells 12. The stamped flat springs 86 can thus help maintain the PV cells 12 within the wells 78 formed at the bottom section 24 of the package 14. In embodiments where the wells 78 are formed into the top section 22 of the package 14, the stamped flat springs 86 can be secured to the top surface 66 of the bottom section 24 and push the PV cells 12 upward into the wells 78.

In embodiments, the stamped flat springs 86 are part of the electrical current collection and transmission components 80. In such embodiments, the stamped flat springs 86 are positioned to contact the busbars 70 available at the top primary surface 18 of the PV cells 12. Thus, the stamped flat springs 86 can serve the dual purpose of mechanically securing the PV cells 12 within the package 14 and conducting the current that the PV cells 12 generate.

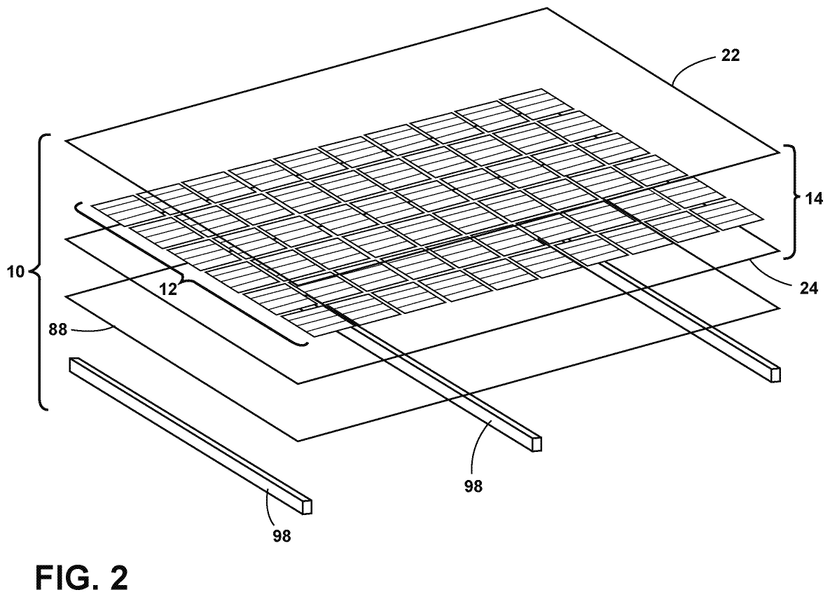

Referring back to FIGS. 2 and 3, in embodiments, the solar panel 10 further includes a backing 88. The backing 88 supports the package 14. The backing 88 is deposed under the package 14. The backing 88 is attached to a bottom surface 91 of the bottom section 24 of the package 14. The backing 88 can be a sheet or film of metal. The metal can be aluminum, among other options. The metal can be anodized. In such instances, the anodization forms a surface layer of metal oxide on the sheet or film of metal. For example, in the instances where the backing 88 is a sheet of aluminum, the anodization of the aluminum forms a surface layer of aluminum oxide (Al₂O₃). The metal oxide surface layer helps slow or prevent corrosion of the backing 88. The backing 88 can be adhered to the bottom section 24 of the package 14 via any of the bonding mechanisms heretofore mentioned, such as anodic bonding, laser bonding, resins, and so on. The backing 88 can be extruded aluminum.

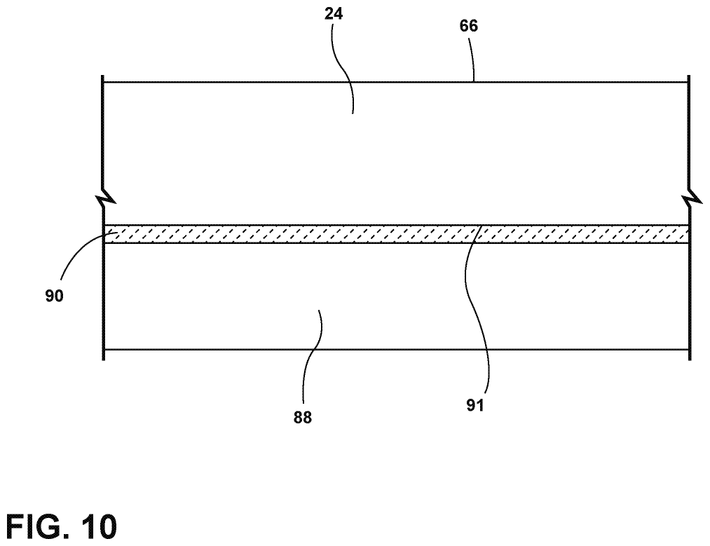

Referring to FIG. 10, in embodiments, the solar panel 10 further includes a thermal transfer fluid 90 disposed between the backing 88 and the bottom surface 91 of the bottom section 24 of the package 14. Suitable examples for the thermal transfer fluid 90 include propylene glycol, ethylene glycol, and silicone oil, among others. This list is not intended to be limiting.

Referring back to FIGS. 1-3, in embodiments, the solar panel 10 includes a heat sink 92. The heat sink 92 can include numerous fins 94. The heat sink 92 increases the surface area from which heat can be transferred from the heat sink 92 (and thus from the solar panel 10) to an external environment 96. The heat sink 92 can be made of metal, such as aluminum. The heat sink 92 can be directly bonded to the backing 88. In embodiments, the backing 88 and the heat sink 92 are integrated. For example, the backing 88 and the heat sink 82 can be formed together from extruded aluminum.

In embodiments, the solar panel 10 further includes one or more stiffeners 98. The one or more stiffeners 98 can be integrated with the backing 88. The one or more stiffeners 98 can be directly bonded to the backing 88. The one or more stiffeners 98 can include hollow metal beams. The one or more stiffeners 98 increase the rigidity of the backing 88 and thus of the solar panel 10. The stiffeners 98 are considered to be different than an external frame 100, which can also be made of a metal such as aluminum.

The solar panel 10 of the present disclosure addresses the aforementioned problems with prior solar panels, in many ways. First, the solar panel 10 is entirely recyclable, except to the extent that the PV cells 12 perhaps themselves are not. The solar panel 10 does not utilize the generally not-recyclable polymeric encapsulants or polyvinyl fluoride (e.g., Tedlar®) backing 88. Rather, the solar panel 10 hermetically seals the PV cells 12 with the package 14, which is made of entirely recyclable glass, glass-ceramic, or metal compositions. The backing 88 is metal, which is much more readily recyclable than polyvinyl fluoride. Further, the solar panel 10 utilizes solder 74 and conductive materials that do not contain lead or other suboptimal metals.

Second, the solar panel 10 protects the PV cells 12 from alkali ion and moisture migration to the PV cells 12. The layers of SiO₂ or SiNₓ disposed (i) between the top primary surfaces of the PV cells 12 and the top section 22 of the package 14 and (ii) between the bottom primary surfaces 20 of the PV cells 12 and the bottom section 24 of the package 14 limit alkali ion migration from the package 14 to the PV cells 12. The polymer based encapsulants of previous solar panels do not adequately limit alkali ion migration. Further, the bonding approaches described to bond the top section 22 and the bottom section 24 of the package 14 together limit or prevent moisture migration from the external environment to the PV cells 12. Anodic bonding, laser bonding, and glass-frit bonding all form a hermetic seal.

Third, the solar panel 10 efficiently transfers heat away from the PV cells 12 to the external environment 96. The solar panel 10 can include a thermally conductive suspension 68 between the PV cells 12 and the bottom section 24 of the package 14. The solar panel 10 can include a backing 88 of metal attached to the package 14. A thermal transfer fluid 90 can be disposed between the backing 88 and the package 14. The heat sink 92 can be integrated with the backing 88 (e.g. formed as a single piece via extrusion). All of these measures separately and together improve heat transfer from the PV cells 12 to the external environment 96. The heat transfer adaptations described, as well as the alkali ion migration prevention layers, allow the solar panels to have a long lifespan likely exceeding 25 years or even 30 years or more.

Directional terms as used herein—for example up, down, right, left, front, back, top, bottom—are made only with reference to the figures as drawn and are not intended to imply absolute orientation.

Unless otherwise expressly stated, it is in no way intended that any method set forth herein be construed as requiring that its steps be performed in a specific order. Accordingly, where a method claim does not actually recite an order to be followed by its steps, or it is not otherwise specifically stated in the claims or descriptions that the steps are to be limited to a specific order, it is in no way intended that an order be inferred, in any respect. This holds for any possible non-express basis for interpretation, including: matters of logic with respect to arrangement of steps or operational flow; plain meaning derived from grammatical organization or punctuation; the number or type of embodiments described in the specification.

As used herein, the singular forms “a,” “an” and “the” include plural referents unless the context clearly dictates otherwise. Thus, for example, reference to a “component” includes aspects having two or more such components, unless the context clearly indicates otherwise.

Many variations and modifications may be made to the above-described embodiments of the disclosure without departing substantially from the spirit and various principles of the disclosure. All such modifications and variations are intended to be included herein within the scope of this disclosure and protected by the following claims.

1. A solar panel comprising:
an array of photovoltaic (PV) cells, each of the PV cells comprising a top primary surface and a bottom primary surface facing away from the top primary surface; and
a package encapsulating the array of PV cells, the package comprising a top section and a bottom section, with the top primary surface of each of the PV cells facing the top section and the bottom primary surface of each of the PV cells facing the bottom section, and with the top section and the bottom section of the package bonded together at a bonded perimeter of the package to form a hermetic seal around the array of PV cells;
wherein, the top section of the package comprises a glass composition or a glass-ceramic composition; and
wherein, the bottom section of the package comprises a glass composition, a glass-ceramic composition, or a metal.

2. (canceled)

3. The solar panel of claim 1, wherein
the top region consists of a glass composition or a glass-ceramic composition.

4. The solar panel of claim 3, wherein
the top region comprises the glass composition, and the glass composition comprises soda lime glass with low iron content, a glass composition with low alkali content, or a mechanically advantaged glass composition.

5. The solar panel of claim 1, wherein
the top section and the bottom section of the package are bonded together at the bonded perimeter via anodic bonding.

6. The solar panel of claim 1, wherein
the top section and the bottom section of the package are bonded together at the bonded perimeter via laser bonding.

7. The solar panel of claim 1, wherein
the package further comprises a bonding material bonding the top section and the bottom section of the package together at the bonded perimeter.

8. The solar panel of claim 7, wherein
the bonding material is a polymer, a glass, or a glass-ceramic.

9. (canceled)

10. The solar panel of claim 1, wherein
the package further includes a middle section disposed between the top section and the bottom section at the bonded perimeter of the package, and
the top section, the middle section, and the bottom section are bonded together.

11. The solar panel of claim 10, wherein
the top section, the middle section, and the bottom section are anodically bonded together.

12. The solar panel of claim 10, wherein
the middle section exhibits a lower glass transition temperature than the top section and the bottom section.

13. (canceled)

14. The solar panel of claim 1 further comprising:
an inert gas disposed between the top section and the bottom section of the package and within the bonded perimeter of the package.

15. (canceled)

16. The solar panel of claim 1 further comprising:
a layer of SiO₂ or SiNₓ disposed between the bottom primary surfaces of the PV cells and a top surface of the bottom section of the package.

17. The solar panel of claim 1 further comprises:
a thermally conductive suspension disposed between the bottom primary surface of each of the PV cells and the bottom section of the package;
wherein, the thermally conductive suspension comprises an oil, a surfactant, and inorganic filler that increases the thermal conductivity of the thermally conductive suspension relative to the oil alone.

18. The solar panel of claim 1, wherein
each PV cell is bonded to the bottom section of the package with a glass composition, a glass-ceramic composition, anodic bonding, laser bonding, or a thermally conductive bonding material.

19. The solar panel of claim 1, wherein
adjacent PV cells are in electrical communication through the incorporation of solder,
the solder comprises one or more electrically conductive metals, and
the solder is substantially free of cadmium, lead, mercury, and hexavalent chromium.

20. The solar panel of claim 1, wherein
adjacent PV cells are in electrical communication through the incorporation of conductive paste,
the conductive paste comprises a mixture of electrically conductive metal particles and a binder material, and
the electrically conductive metal particles are substantially free of cadmium, lead, mercury, and hexavalent chromium.

21.-32. (canceled)

33. A solar panel comprising:
an array of photovoltaic (PV) cells, each of the PV cells comprising a top primary surface and a bottom primary surface facing away from the top primary surface;
a package encapsulating the array of PV cells, the package comprising a top section comprising a glass composition and a bottom section, with the top primary surface of each of the PV cells facing the top section and the bottom primary surface of each of the PV cells facing the bottom section, and with the top section and the bottom section of the package bonded together at a bonded perimeter of the package to form a hermetic seal around the array of PV cells;
a layer of SiO₂ or SiNₓ disposed between the bottom primary surfaces of the PV cells and a top surface of the bottom section of the package; and
an antireflective coating disposed on a bottom surface of the top section of the package facing the top primary surfaces of the PV cells, the antireflective coating comprises at least one layer of SiO₂ or SiNₓ.

34. A solar panel comprising:
an array of photovoltaic (PV) cells, each of the PV cells comprising a top primary surface and a bottom primary surface facing away from the top primary surface;
a package encapsulating the array of PV cells, the package comprising a top section comprising a glass composition and a bottom section, with the top primary surface of each of the PV cells facing the top section and the bottom primary surface of each of the PV cells facing the bottom section, and with the top section and the bottom section of the package bonded together at a bonded perimeter of the package to form a hermetic seal around the array of PV cells;
a backing supporting the package, the backing comprising a sheet or film of metal; and
a thermal transfer fluid disposed between the backing and the package.

35. The solar panel of claim 34 further comprising:
a heat sink integrated formed with the backing via extrusion of a metal.

36. The solar panel of claim 34 further comprising:
a thermally conductive suspension disposed between the bottom primary surface of each of the PV cells and the bottom section of the package;
wherein, the thermally conductive suspension comprises an oil, a surfactant, and inorganic filler that increases the thermal conductivity of the thermally conductive suspension relative to the oil alone.
